(19) United States
(12) Patent Application Publication
(10) Pub. No.: US 2016/0380119 A1
(43) Pub. Date: Dec. 29, 2016

(54) SEMICONDUCTOR DEVICE AND METHOD OF MANUFACTURING THE SAME

(71) Applicant: ELECTRONICS AND TELECOMMUNICATIONS RESEARCH INSTITUTE, Daejeon (KR)

(72) Inventors: Dong Yun JUNG, Daejeon (KR); Hyun Soo LEE, Goyang-si (KR); Sang Choon KO, Daejeon (KR); Jeong-Jin KIM, Jeonju-si (KR); Zin-Sig KIM, Daejeon (KR); Jeho NA, Seoul (KR); Eun Soo NAM, Daejeon (KR); Jae Kyoung MUN, Daejeon (KR); Young Rak PARK, Daejeon (KR); Sung-Bum BAE, Daejeon (KR); Hyung Seok LEE, Daejeon (KR); Woojin CHANG, Daejeon (KR); Hyungyu JANG, Cheongju-si (KR); Chi Hoon JUN, Daejeon (KR)

(73) Assignee: ELECTRONICS AND TELECOMMUNICATIONS RESEARCH INSTITUTE, Daejeon (KR)

(21) Appl. No.: 15/084,874

(22) Filed: Mar. 30, 2016

(30) Foreign Application Priority Data
Jun. 23, 2015 (KR) 10-2015-0088941

(51) Int. Cl. H01L 29/872; H01L 29/205; H01L 29/45; H01L 21/02; H01L 23/29; H01L 29/47; H01L 29/66; H01L 21/306; H01L 29/20; H01L 23/31

(52) U.S. Cl. CPC H01L 29/8725; H01L 29/2003; H01L 29/205; H01L 29/452; H01L 23/3171; H01L 23/291; H01L 29/475; H01L 29/66212; H01L 21/30612; H01L 21/02178; H01L 21/0228

(57) ABSTRACT

A first nitride semiconductor layer of a semiconductor device is provided on a substrate, a second nitride semiconductor layer is provided on the first nitride semiconductor layer, a first ohmic metal and a second ohmic metal are provided on the second nitride semiconductor layer, a recess region is provided in the second nitride semiconductor layer between the first ohmic metal and the second ohmic metal, a passivation layer covers side of the first ohmic metal and a bottom surface and sides of the recess region, and a Schottky electrode is provided on the first ohmic metal and extends into the recess region.

### CROSS-REFERENCE TO RELATED APPLICATIONS

This U.S. non-provisional patent application claims priority under 35 U.S.C. §119 of Korean Patent Application No. 10-2015-0088941, filed on Jun. 23, 2015, the entire contents of which are hereby incorporated by reference.

### BACKGROUND OF THE INVENTION

The present disclosure herein relates to semiconductor devices, and more particularly, to nitride semiconductor devices having a Schottky electrode.

In general, important parameters of a Schottky barrier diode (SBD) include forward characteristics, such as turn-on voltage (VT) and forward current (IF), and reverse characteristics such as breakdown voltage (VBD) and reverse leakage current (IR).

The related art for improving the forward characteristics may include a decrease in distance between a Schottky electrode and an ohmic electrode, an anode structure in which the Schottky electrode and the ohmic electrode are combined, a Bonding Pad Over Active (BPOA) structure, silicon doping in an anode region and a cathode region, and a method of using a nitride-based passivation layer.

The related art for improving the reverse characteristics may include an increase in the distance between the Schottky electrode and the ohmic electrode, a field plate structure, recess of the anode region, and use of an oxide-based passivation layer.

### SUMMARY OF THE INVENTION

The present disclosure provides a semiconductor device having improved reverse characteristics and forward characteristics.

An embodiment of the inventive concept provides a semiconductor device including a first nitride semiconductor layer on a substrate; a second nitride semiconductor layer on the first nitride semiconductor layer; a first ohmic metal and a second ohmic metal on the second nitride semiconductor layer; a recess region provided in the second nitride semiconductor layer between the first ohmic metal and the second ohmic metal; a passivation layer configured to cover side of the first ohmic metal and a bottom surface and sides of the recess region; and a Schottky electrode which is provided on the first ohmic metal and extends into the recess region.

In an embodiment, the first nitride semiconductor layer may include GaN and the second nitride semiconductor layer may include any one selected from the group consisting of AlGaN, InAlN, and InAlGaN.

In an embodiment, at least one of the first ohmic metal and the second ohmic metal may include titanium (Ti), aluminum (Al), nickel (Ni), and gold (Au).

In an embodiment, one side of the recess region may be aligned with one side of the first ohmic metal.

In an embodiment, the passivation layer may include Al₂O₃.

In an embodiment, the Schottky electrode may further be formed from the recess region toward the second ohmic metal.

In an embodiment, the Schottky electrode may include Ni and Au.

In an embodiment, a capping layer may be disposed between the passivation layer and the second nitride semiconductor layer.

In an embodiment, a capping layer including GaN may be disposed between the passivation layer and the second nitride semiconductor layer.

In an embodiment of the inventive concept, a method of manufacturing a semiconductor device includes providing a first nitride semiconductor layer on a substrate; providing a second nitride semiconductor layer on the first nitride semiconductor layer; forming a first ohmic metal and a second ohmic metal on the second nitride semiconductor layer; forming a recess region in the second nitride semiconductor layer between the first ohmic metal and the second ohmic metal; forming a passivation layer to cover side of the first ohmic metal and a bottom surface and sides of the recess region; and forming a Schottky electrode which is provided on the first ohmic metal and fills the recess region.

In an embodiment, the forming of at least one of the first ohmic metal and the second ohmic metal may include forming an ohmic metal including titanium (Ti), aluminum (Al), nickel (Ni), and gold (Au) on the second nitride semiconductor layer; and performing a heat treatment on the ohmic metal.

In an embodiment, the forming of the passivation layer may include atomic layer deposition.

In an embodiment, the method may further include forming a capping layer between the passivation layer and the second nitride semiconductor layer.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view illustrating a semiconductor device according to an embodiment of the inventive concept;

FIG. 2 is a cross-sectional view illustrating a semiconductor device according to another embodiment of the inventive concept; and

FIGS. 3 through 10 are cross-sectional views illustrating a method of manufacturing a semiconductor device according to an embodiment of the inventive concept.

### DETAILED DESCRIPTION OF PREFERRED EMBODIMENTS

The foregoing and other objects, features and advantages of the present disclosure will become more readily apparent from the following detailed description of preferred embodiments of the present disclosure that proceeds with reference to the appending drawings. The present disclosure may, however, be embodied in different forms and should not be construed as limited to the embodiments set forth herein. Rather, these embodiments are provided so that this disclosure will be thorough and complete, and will fully convey the scope of the inventive concept to those skilled in the art.

In this specification, it will be understood that when a film (or layer) is referred to as being “on” another film (or layer) or substrate, it can be directly on the other film (or layer) or substrate, or intervening films (or layers) may also be present therebetween. Also, in the figures, the sizes and thicknesses of elements are exaggerated for clarity of illustration. Furthermore, though terms like a first, a second, and a third are used to describe various directions and films (or layers) in various embodiments of the present invention, the directions and the films (or layers) are not limited to these terms. These terms are used only to discriminate one direction or film (or layer) from another direction or film (or layer). Therefore, a film referred to as a first film (or layer) in one embodiment can be referred to as a second film (or layer) in another embodiment. An embodiment described and exemplified herein includes a complementary embodiment thereof. Like reference numerals refer to like elements throughout.

Hereinafter, embodiments of the inventive concept will be described in detail with reference to the accompanying drawings. Although a case is described in which a semiconductor device according to an embodiment of the inventive concept is a Schottky diode, the embodiment of the inventive concept is not limited thereto.

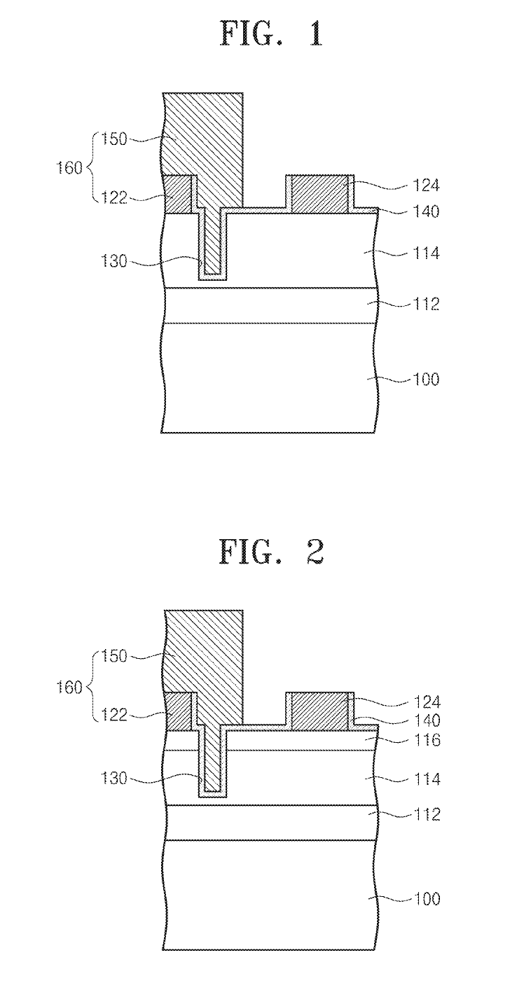

FIG. 1 is a cross-sectional view illustrating a semiconductor device according to an embodiment of the inventive concept. Referring to FIG. 1, a substrate, a first nitride semiconductor layer, a second nitride semiconductor layer, a first ohmic metal, a second ohmic metal, a Schottky electrode, and a passivation layer may be provided.

A substrate 100 may be a high resistance substrate having insulating properties. For example, the substrate 100 may include aluminum oxide (Al₂O₃), silicon (Si), gallium arsenide (GaAs), silicon carbide (SiC), or gallium nitride (GaN).

A first nitride semiconductor layer 112 and a second nitride semiconductor layer 114 may be provided on the substrate 100. The first nitride semiconductor layer 112 and the second nitride semiconductor layer 114 may have a heterojunction structure. The first nitride semiconductor layer 112 and the second nitride semiconductor layer 114 may include materials forming a 2-dimensional electron gas (2-DEG) layer at an interface. For example, the first nitride semiconductor layer 112 may include GaN. The second nitride semiconductor layer 114 may include any one selected from the group consisting of AlGaN, InAlN, and InAlGaN. The first nitride semiconductor layer 112 and the second nitride semiconductor layer 114 may be epitaxial layers. When the first nitride semiconductor layer 112 is the epitaxial layer, the semiconductor device may have a high breakdown voltage characteristic.

The first nitride semiconductor layer 112 may be a buffer layer. The buffer layer may be provided to address limitations due to lattice mismatch between the substrate 100 and the second nitride semiconductor layer 114. In another example, a buffer layer may be included between the substrate 100 and the first nitride semiconductor layer 112. The buffer layer may include GaN.

A second ohmic metal 124 and a first ohmic metal 122 may be disposed on the second nitride semiconductor layer 114. For example, the first ohmic metal 122 may be an ohmic metal of an anode electrode 160. The second ohmic metal 124 may be a cathode electrode. When viewed from the top, the second ohmic metal 124 and the first ohmic metal 122 may be horizontally spaced apart from each other.

At least one of the second ohmic metal 124 and the first ohmic metal 122 may include titanium (Ti), aluminum (Al), nickel (Ni), and gold (Au). The second ohmic metal 124 and the first ohmic metal 122 may be electrically connected to the second nitride semiconductor layer 114.

A recess region 130 may be provided in the second nitride semiconductor layer 114 between the first ohmic metal 122 and the second ohmic metal 124. A bottom surface of the recess region 130 may be near a bottom surface of the second nitride semiconductor layer 114. When viewed from the top, the recess region 130 may be closer to the first ohmic metal 122 than the second ohmic metal 124. For example, one sidewall of the recess region 130 may be aligned with one side of the first ohmic metal 122.

A Schottky electrode 150 may be provided in the recess region 130 and on the first ohmic metal 122. The first ohmic metal 122 and the Schottky electrode 150 may be in contact with each other to provide the anode electrode 160. The Schottky electrode 150 may be horizontally spaced apart from the second ohmic metal 124. The Schottky electrode 150 may include a plurality of conductive materials. For example, the Schottky electrode 150 may include Ni and Au.

The Schottky electrode 150 may be electrically connected to the first ohmic metal 122. When a forward bias is applied to the semiconductor device, a current may further flow through the first ohmic metal 122 as well as the Schottky electrode 150 in the recess region 130. Accordingly, a semiconductor device having improved forward current characteristics may be provided. The Schottky electrode 150 may be in contact with the second nitride semiconductor layer 114 to form a depletion layer in the 2-dimensional electron gas (2-DEG) layer. When a reverse bias is applied to the semiconductor device, the depletion layer may be reinforced. Accordingly, a semiconductor device having improved leakage current prevention characteristics may be provided.

A passivation layer 140 may be disposed between the Schottky electrode 150 and the second nitride semiconductor layer 114. The passivation layer 140 may cover sides of the first ohmic metal 122 and the second ohmic metal 124. The passivation layer 140 may be provided on the bottom surface and sides of the recess region 130. For example, the passivation layer 140 may include aluminum oxide (Al₂O₃). The Al₂O₃ may have a higher breakdown voltage and a lower capacitance than other passivation materials. Accordingly, the Al₂O₃ passivation may reduce a reverse leakage current of the semiconductor device. Eventually, a semiconductor device having improved reverse characteristics may be provided.

FIG. 2 is a cross-sectional view illustrating a semiconductor device according to another embodiment of the inventive concept. Referring to FIG. 2, a substrate, a first nitride semiconductor layer, a second nitride semiconductor layer, a capping layer, a first ohmic metal, a second ohmic metal, a Schottky electrode, and a passivation layer may be provided.

Detailed descriptions of the same elements as those of the Schottky diode in the embodiment previously described with reference to FIG. 1 will be omitted to avoid a repeated description.

A capping layer 116 may be disposed between a second ohmic metal 124 and a second nitride semiconductor layer 114 and between a first ohmic metal 122 and the second nitride semiconductor layer 114. The capping layer 116 may include a recess region 130 configured to penetrate the capping layer 116. The capping layer 116 may protect a surface of the semiconductor device and may reduce a leakage current. For example, the capping layer 116 may include GaN.

A Schottky electrode 150 may penetrate through the capping layer 116 to extend into the second nitride semiconductor layer 114.

In the above description, the Schottky diodes have been described in which the Al₂O₃ passivation layer 140 is disposed between the Schottky electrode 150 and the recess region 130. The Al₂O₃ passivation layer 140 may reduce the leakage current of the Schottky diode. Accordingly, a Schottky diode having improved reverse characteristics may be provided.

Hereinafter, a method of manufacturing a semiconductor device according to an embodiment of the inventive concept will be described.

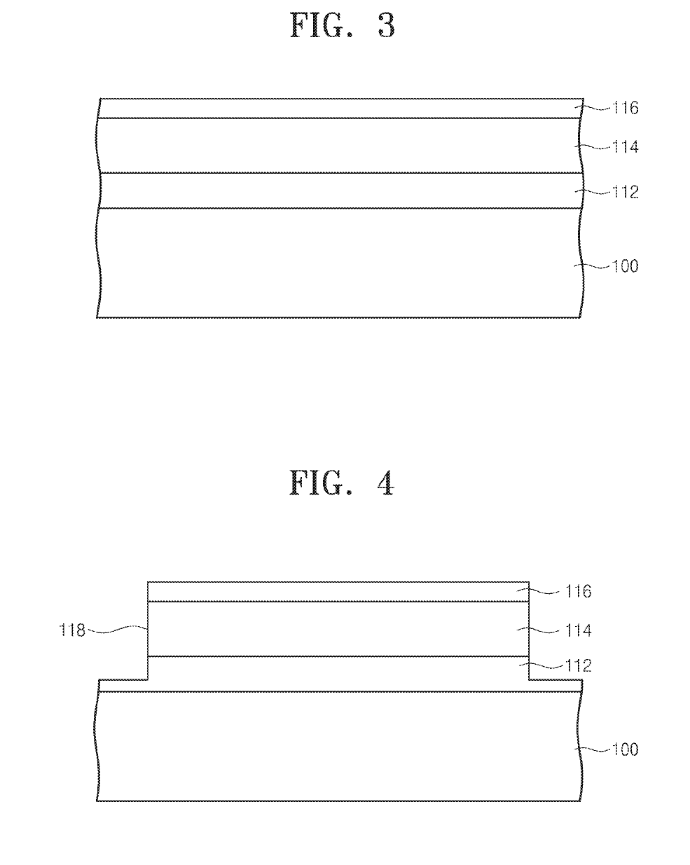

FIGS. 3 through 10 are cross-sectional views illustrating a method of manufacturing a semiconductor device according to an embodiment of the inventive concept. Referring to FIGS. 3 to 10, a substrate, a first nitride semiconductor layer, a second nitride semiconductor layer, a capping layer, a passivation layer, a first ohmic metal, a second ohmic metal, and a Schottky electrode may be provided.

Referring to FIG. 3, a substrate 100 may be provided. The substrate 100 may include aluminum oxide (Al₂O₃), silicon carbide (SiC), or silicon (Si). For example, the Si substrate 100 having a thickness of about 625 nm may be provided.

A first nitride semiconductor layer 112 and a second nitride semiconductor layer 114 may be provided on the substrate 100. For example, the first nitride semiconductor layer 112 and the second nitride semiconductor layer 114 may be formed by an epitaxial growth process. For example, the epitaxial growth process may include at least one of metal organic chemical vapor deposition, liquid phase epitaxy, hydride vapor phase epitaxy, molecular beam epitaxy, or metal organic vapor phase epitaxy (MOVPE). For example, the first nitride semiconductor layer 112 may include GaN having a thickness of about 3 μm to about 4 μm. The second nitride semiconductor layer 114 may include AlGaN having a thickness of about 20 nm.

A capping layer 116 may be provided on the second nitride semiconductor layer 114. The capping layer 116 may be formed by an epitaxial growth process. For example, the epitaxial growth process may include at least one of metal organic chemical vapor deposition, liquid phase epitaxy, hydride vapor phase epitaxy, molecular beam epitaxy, or MOVPE. For example, the capping layer 116 may include GaN having a thickness of about 1.25 nm.

Additionally, referring to FIG. 4, isolation regions 118 may be formed at boundaries of the semiconductor device. The isolation regions 118 may be formed from a top surface of the capping layer 116 to the inside of the first nitride semiconductor layer 112. Bottom surfaces of the isolation regions 118 may be near a bottom surface of the first nitride semiconductor layer 112. The isolation regions 118 may be dry etched or wet etched by using an etch mask (not shown). For example, a process of forming the isolation regions 118 may include inductively coupled plasma reactive ion etching (ICP RIE) using BCl₃/Cl₂ gas. For example, the isolation regions 118 may have a depth of about 2,000 angstroms.

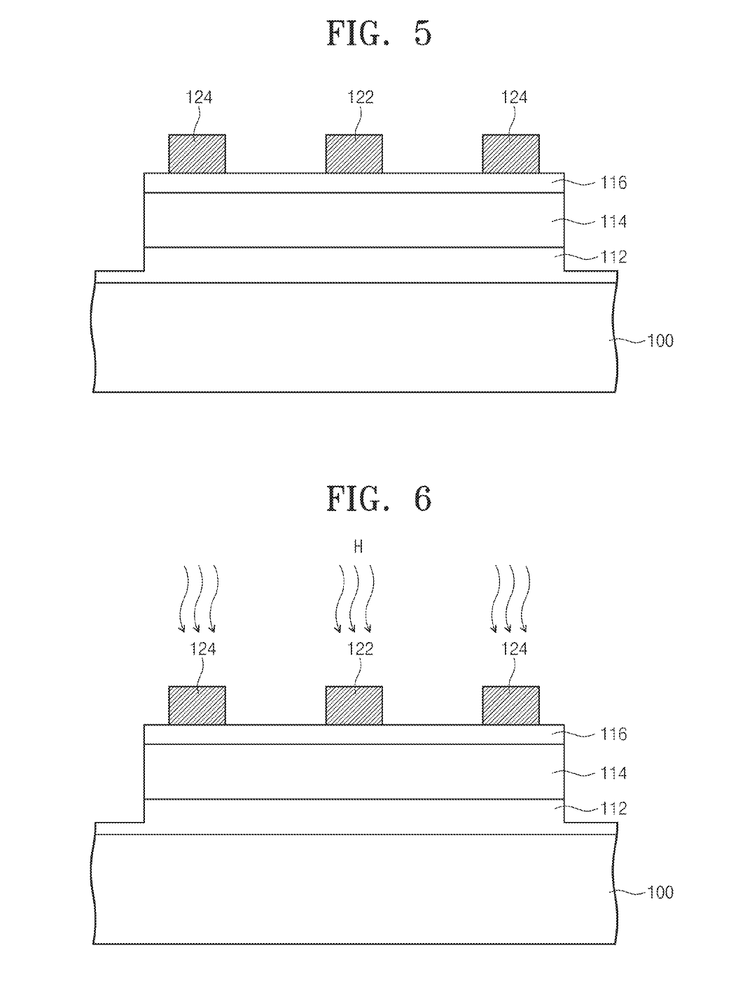

Referring to FIGS. 5 and 6, a first ohmic metal 122 and second ohmic metals 124 may be formed on the capping layer 116. For example, the first ohmic metal 122 may be an ohmic metal of an anode electrode 160. The second ohmic metals 124 may be cathode electrodes. A process of forming the first ohmic metal 122 and the second ohmic metals 124 may include electron beam (E-beam) deposition. The electrodes 122 and 124 may include a metal or a plurality of metals sequentially formed. For example, the electrodes 122 and 124 may include about 20 nm thick titanium (Ti), about 100 nm thick aluminum (Al), about 25 nm thick nickel (Ni), and about 50 nm thick gold (Au).

The first ohmic metal 122 and the second ohmic metals 124 may be formed to be horizontally spaced apart from one another. For example, when viewed from the top, a spacing between a Schottky electrode 150 and the second ohmic metals 124 may be in a range of about 15 μm to about 20 μm.

The first ohmic metal 122 and the second ohmic metals 124 may be subjected to a heat treatment H. For example, the heat treatment H may be performed on the electrodes 122 and 124 at 880° C. for 1 minute in a nitrogen (N₂) atmosphere. The electrodes 122 and 124 may be in ohmic contact with the capping layer 116 or the second nitride semiconductor layer 114 through the heat treatment H.

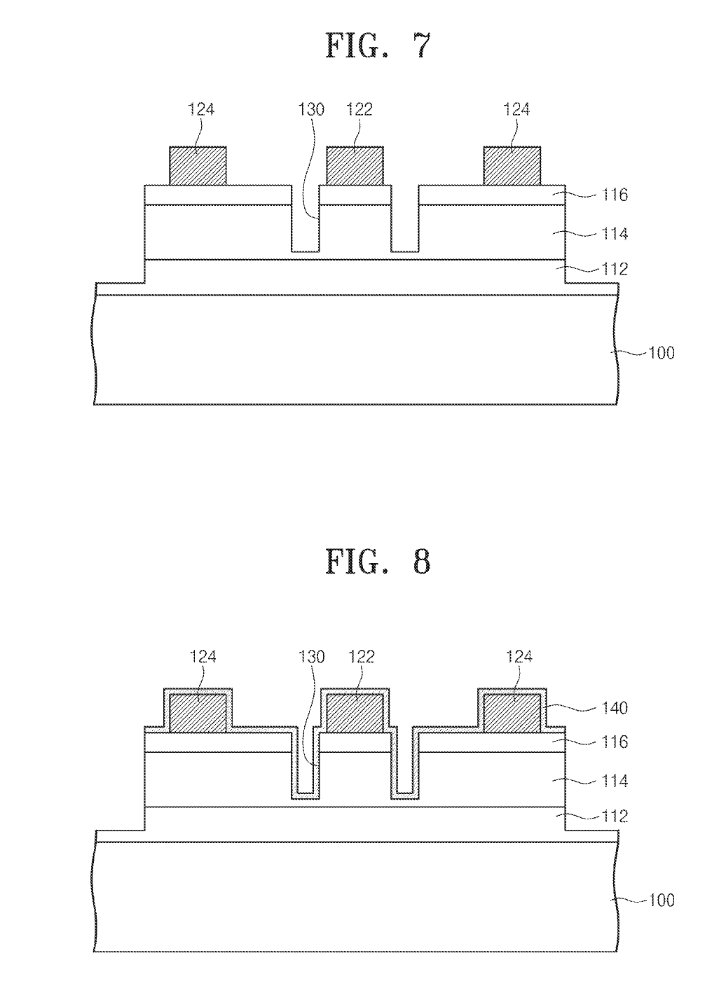

Referring to FIG. 7, recess regions 130 may be formed in the second nitride semiconductor layer 114 between the second ohmic metals 124 and the first ohmic metal 122. The capping layer 116 may be penetrated by the recess region 130. A process of forming the recess region 130 may include dry etching or wet etching the capping layer 116 and the second nitride semiconductor layer 114 using an etch mask. For example, the process of forming the recess region 130 may include inductively coupled plasma reactive ion etching (ICP RIE) using BCl₃/Cl₂ gas. For example, the recess region 130 may have a width of about 3 μm. The recess region 130 may have a depth of about 18 nm.

Referring to FIG. 8, a passivation layer 140 configured to cover the first ohmic metal 122, the second ohmic metal 124, the capping layer 116, and the second nitride semiconductor layer 114 may be formed. The passivation layer 140 may be formed on a bottom surface and sides of the recess region 130. A process of forming the passivation layer 140 may include any one selected from the group consisting of atomic layer deposition (ALD), molecular beam epitaxy (MBE), and thermal oxidation. For example, the passivation layer 140, which includes aluminum oxide (Al₂O₃) having a thickness of about 7 nm to about 15 nm, may be formed by the ALD. The passivation layer 140 may be uniformly deposited by the ALD. A uniform passivation layer may have a smaller leakage current than a non-uniform passivation layer. Accordingly, a semiconductor device having improved reverse characteristics may be formed.

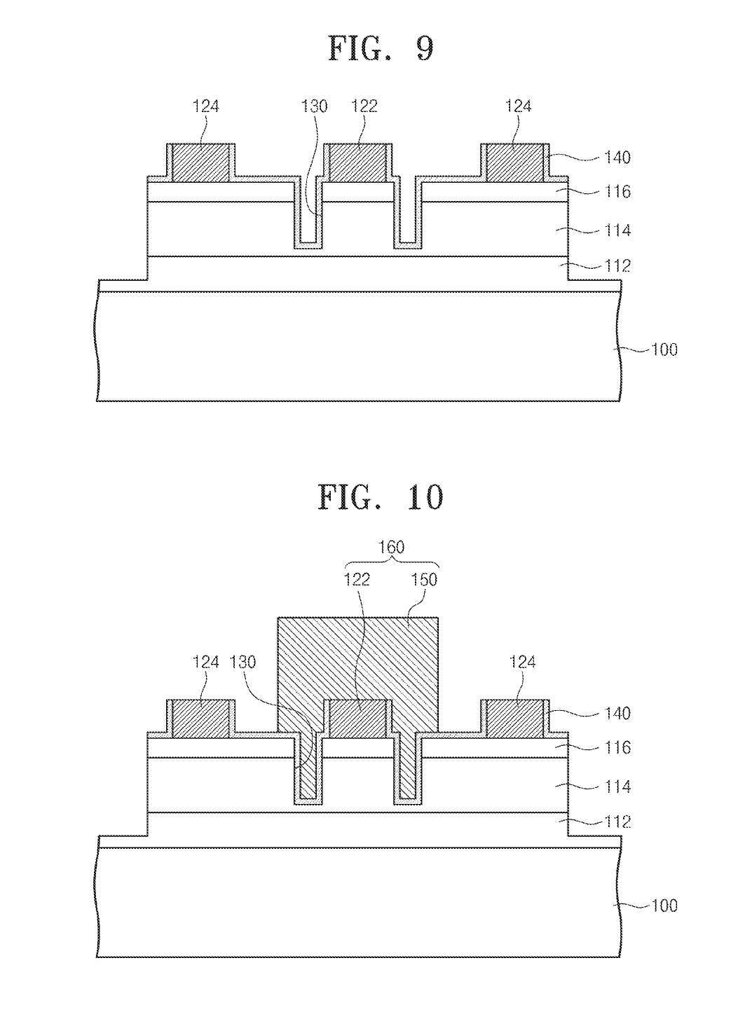

Referring to FIG. 9, the passivation layer 140 on the first ohmic metal 122 and the second ohmic metals 124 may be removed. A process of removing the passivation layer 140 may include an etching or polishing process. For example, the passivation layer 140 may be subjected to buffered oxide etch (BOE). Accordingly, a top surface of the first ohmic metal 122 and top surfaces of the second ohmic metals 124 may be exposed.

Referring to FIG. 10, the Schottky electrode 150 may be formed on the first ohmic metal 122. The Schottky electrode 150 may fill the recess regions 130. The Schottky electrode 150 may further be formed from end portions of the recess regions 130 toward the second ohmic metals 124. For example, the Schottky electrode 150 may further be formed to a length of about 1 μm from the recess regions 130 toward the second ohmic metals 124. For example, a process of forming the Schottky electrode 150 may include E-beam deposition. The Schottky electrode 150 may include a plurality of metals. For example, the Schottky electrode 150 may be formed by depositing about 30 nm thick Ni and about 400 nm thick Au.

According to embodiments of the inventive concept, a Schottky electrode, which is provided on an ohmic metal and extends to a recess region, may be provided. Accordingly, a semiconductor device having improved forward characteristics may be provided.

According to embodiments of the inventive concept, a passivation layer may be provided between the Schottky electrode and the recess region. Accordingly, a semiconductor device having improved reverse characteristics may be provided.

However, effects of the semiconductor device according to the inventive concept are not limited to the above-described effects.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Accordingly, the exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A semiconductor device comprising:
a first nitride semiconductor layer on a substrate;
a second nitride semiconductor layer on the first nitride semiconductor layer;
a first ohmic metal and a second ohmic metal on the second nitride semiconductor layer;
a recess region provided in the second nitride semiconductor layer between the first ohmic metal and the second ohmic metal;
a passivation layer configured to cover side of the first ohmic metal and a bottom surface and sides of the recess region; and
a Schottky electrode which is provided on the first ohmic metal and extends into the recess region.

2. The semiconductor device of claim 1, wherein the first nitride semiconductor layer comprises GaN and the second nitride semiconductor layer comprises any one selected from the group consisting of AlGaN, InAlN, and InAlGaN.

3. The semiconductor device of claim 1, wherein at least one of the first ohmic metal and the second ohmic metal comprises titanium (Ti), aluminum (Al), nickel (Ni), and gold (Au).

4. The semiconductor device of claim 1, wherein one side of the recess region is aligned with one side of the first ohmic metal.

5. The semiconductor device of claim 1, wherein the passivation layer comprises Al₂O₃.

6. The semiconductor device of claim 1, wherein the Schottky electrode is further formed from the recess region toward the second ohmic metal.

7. The semiconductor device of claim 1, wherein the Schottky electrode comprises Ni and Au.

8. The semiconductor device of claim 1, wherein a capping layer is disposed between the passivation layer and the second nitride semiconductor layer.

9. The semiconductor device of claim 1, wherein a capping layer comprising GaN is disposed between the passivation layer and the second nitride semiconductor layer.

10. A method of manufacturing a semiconductor device, the method comprising:
providing a first nitride semiconductor layer on a substrate;
providing a second nitride semiconductor layer on the first nitride semiconductor layer;
forming a first ohmic metal and a second ohmic metal on the second nitride semiconductor layer;
forming a recess region in the second nitride semiconductor layer between the first ohmic metal and the second ohmic metal;
forming a passivation layer to cover side of the first ohmic metal and a bottom surface and sides of the recess region; and
forming a Schottky electrode which is provided on the first ohmic metal and fills the recess region.

11. The method of claim 10, wherein the forming of at least one of the first ohmic metal and the second ohmic metal comprises:
forming an ohmic metal including titanium (Ti), aluminum (Al), nickel (Ni), and gold (Au) on the second nitride semiconductor layer; and
performing a heat treatment on the ohmic metal.

12. The method of claim 10, wherein the forming of the passivation layer comprises atomic layer deposition.

13. The method of claim 10, further comprising forming a capping layer between the passivation layer and the second nitride semiconductor layer.
